(19) United States
(12) Patent Application Publication
(10) Pub. No.: US 2023/0327540 A1
(43) Pub. Date: Oct. 12, 2023

(54) ADJUSTABLE THREE OUTPUT DC VOLTAGE SUPPLY WITH SHORT CIRCUIT PROTECTION

(71) Applicant: Murata Manufacturing Co., Ltd., Nagaokakyo-shi (JP)

(72) Inventor: Frank WARNES, Milton Keynes (GB)

(21) Appl. No.: 18/210,793

(22) Filed: Jun. 16, 2023

Related U.S. Application Data
(63) Continuation of application No. PCT/GB2021/053356, filed on Dec. 17, 2021.

(30) Foreign Application Priority Data
Dec. 18, 2020 (GB) 2020177.8

(51) Int. Cl. H02M 1/32; H02M 3/06; H02M 1/08

(52) U.S. Cl. CPC H02M 1/32; H02M 3/06; H02M 1/08

(57) ABSTRACT

An adjustable three output DC voltage supply circuit includes positive and negative DC voltage buses that connect to a DC power source; a first voltage divider connected between the positive and negative DC voltage buses and including a shunt regulator that is connected to the positive DC voltage bus and that provides an intermediate voltage supply; a second voltage divider connected between the positive or the negative DC voltage bus and the intermediate voltage supply and including an output that is connected to a reference input of the shunt regulator; and a short circuit protection component connected in series to a low voltage side of the shunt regulator and configured to limit the current through the shunt regulator in the case of a short circuit to the intermediate voltage supply.

### CROSS REFERENCE TO RELATED APPLICATIONS

This application claims priority to GB Patent Application No. 2020177.8 filed on Dec. 18, 2020 and is a Continuation Application of PCT Application No. PCT/GB2021/053356 filed on Dec. 17, 2021. The entire contents of each application are hereby incorporated by reference.

### BACKGROUND OF THE INVENTION

### 1. Field of the Invention

The application relates to an adjustable three output DC voltage supply with short circuit protection and, in particular, to adjustable three output DC voltage supplies for gate driving of transistors.

### 2. Description of the Related Art

Three output DC voltage supplies are used with components or circuits which require a positive, intermediate, and negative voltage supply.

One application of such a power supply is driving the gate of transistors, such as insulated gate bipolar transistors (IGBTs), Silicon Carbide (SiC), Gallium Nitride (GaN), and other metal oxide semiconductor field effect transistors (MOSFETs). Transistors such as these transistors require a specific positive and negative gate voltages to turn them on or off. In these cases, the power supply will provide a positive (+v), neutral (0V) and negative (−v) voltage supply, which is achieved by connecting the intermediate voltage output to a ground reference.

Known three output DC voltage supplies provide a precise voltage drop between the intermediate voltage output terminal and either the positive or negative voltage output terminals, by inserting a Zener diode between the appropriate voltage outputs. The remaining voltage is absorbed by a resistor connected in series with the Zener diode. In this sense, the resistor and the Zener diode provide a voltage divider where the center of the voltage divider provides the intermediate voltage output. FIGS. 1 and 2 provide examples of such three output DC voltage supplies.

However, this means that to change the voltage drop provided across either the positive or negative DC output and the intermediate DC output, the Zener diode requires changing. This is a relatively costly component compared to a resistor, so it would be beneficial to provide an adjustable three output DC voltage supply which uses a voltage regulator which can be adjusted by replacing or adjusting a relatively inexpensive component, such as resistor.

Furthermore, if a short circuit is presented across the resistor of the voltage divider, the total voltage will be applied across the Zener diode, and the Zener diode will breakdown, causing a large current to flow. There is no limit to this current through the Zener diode. This means that the Zener diode is exposed to an overvoltage and can become damaged. It would be beneficial to protect the Zener diode, or voltage regulator, in the event of a short circuit.

### SUMMARY OF THE INVENTION

An adjustable three output DC voltage supply according to the preferred embodiments of the present invention provides a positive, intermediate, and negative voltage supply, as well as a positive DC voltage bus and a negative DC voltage bus that connect to a DC power source, a first voltage divider connected between the positive DC voltage bus and the negative DC voltage bus, the first voltage divider including a shunt regulator connected to the positive DC voltage bus and including a reference input, and the output of the first voltage divider providing the intermediate voltage supply. The power supply circuit also includes a second voltage divider connected between either one of the positive DC voltage bus or the negative DC voltage bus and the intermediate voltage supply, and an output of the second voltage divider is connected to the reference input of the shunt regulator. The power supply circuit also includes a short circuit protection component that is connected in series to the low voltage side of the shunt regulator and that is configured to limit the current through the shunt regulator in the case of a short circuit to the intermediate voltage supply.

The short circuit protection component operates to reduce the current and power dissipated in the shunt regulator when a short circuit occurs to the intermediate voltage output terminal. In particular, when a short circuit is present and the intermediate output voltage terminal receives an over or under voltage, the shunt regulator can be damaged by passing an uncontrolled amount of current. The second voltage divider ensures in normal operation that the shunt regulator provides a fixed voltage drop, which is a portion of the supply voltage. The remaining supply voltage is dropped over the second half of the first voltage divider. When this second half is bypassed, by a short circuit at the load, the entire supply voltage can be applied across the shunt regulator. Because in this case there is essentially no load, the current through the regulator increases. The short circuit protection component, in combination with the second voltage divider, limits this current. In normal operation of the circuit, minimal power loss is caused by the short circuit protection component.

The shunt regulator of the adjustable three output DC voltage supply can be connected to either the positive DC voltage bus or the negative DC voltage bus via a resistor.

In these cases, the short circuit protection component is connected between the shunt regulator and the output of the first voltage divider.

The short circuit protection component of the adjustable three output DC voltage supply according to an alternative preferred embodiment of the present invention is connected to the negative DC voltage bus.

In these cases, the shunt regulator is connected between the short circuit protection component and the output of the first voltage divider.

The shunt regulator includes a transistor.

This arrangement of components allows a reference input to be used to switch on a transistor to open or close a “bypass” of the second voltage divider. When the second voltage divider output is equal to the reference voltage of the transistor, then the transistor can be switched to a closed circuit. The components of the second voltage divider are chosen so that this reference voltage is output when the voltage across the second voltage divider is the intended output voltage between the positive or negative supply and the intermediate supply.

The shunt regulator can include a comparator which operates the transistor when an input to the comparator is higher than the reference input of the shunt regulator.

The comparator allows a specific reference voltage to be specified which is independent of the intrinsic collector voltage of the transistor. This allows the circuit designer to maintain appropriate values of the second voltage divider.

The transistor can be a Bipolar Junction Transistor (BJT). BJTs are relatively cheap components and so the use of a BJT can reduce the cost of the circuit.

The transistor can include an intrinsic body diode. In this case, the transistor may be a Field Effect Transistor (FET).

A FET includes a diode which is caused by connection of one of the terminals to the body of the FET itself, called a body diode. This usually means that the transistor can only block current in one direction when switched off. In this case when a diode is needed, a FET provides this diode without the need for adding additional components.

The shunt regulator can include an adjustable reference diode.

This provides a solid state single component to take on the task of regulating the voltage outputs of the circuit, while also allowing an adjustment of this voltage to be made, either internally to the component or by the provision of a set reference voltage which can be provided at different supply voltages based on external components.

The short circuit protection component can include a short circuit protection resistor.

The first voltage divider can include a resistor.

The second voltage divider can include a first setting resistor and a second setting resistor.

The power source can be a rectified output from a transformer.

The adjustable three output DC voltage supply is designed to be connected to a DC power source; however, this does not have to be an absolute DC power source such as would be provided by a battery or the like, but can also be an approximate DC power source such as the output of a converter, i.e. the rectified output of a transformer.

The above problems can be solved in a synergistic manner, that is, that the supply can be configured to be adjustable also contributes to protecting the Zener diode or other regulator.

The intermediate voltage supply of the three output DC voltage power supply may be a 0V voltage supply.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a first example circuit diagram of a known three output DC voltage supply.

FIG. 2 is a second example circuit diagram of a known three output DC voltage supply.

FIGS. 3A and 3B show circuits of comparative examples.

FIG. 4 is a circuit diagram of a three output DC voltage supply with short circuit protection according to a preferred embodiment of the present invention.

FIG. 5 is an example representation of power and current dissipation through the shunt regulator and current dissipation through the short circuit protection component of FIG. 4.

FIG. 6 is a circuit diagram of a three output DC voltage supply with short circuit protection according to a further preferred embodiment of the present invention.

### DETAILED DESCRIPTION OF THE PREFERRED EMBODIMENTS

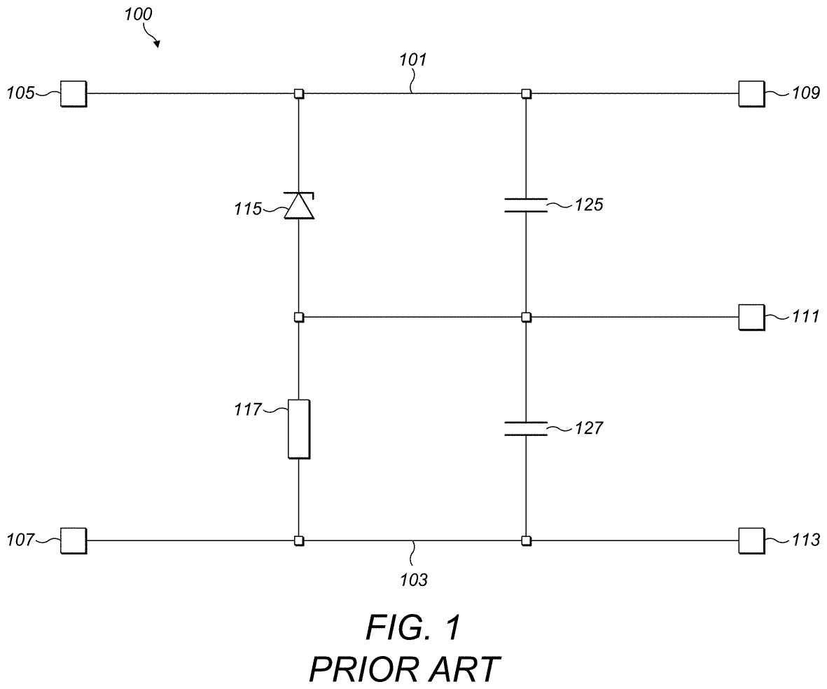

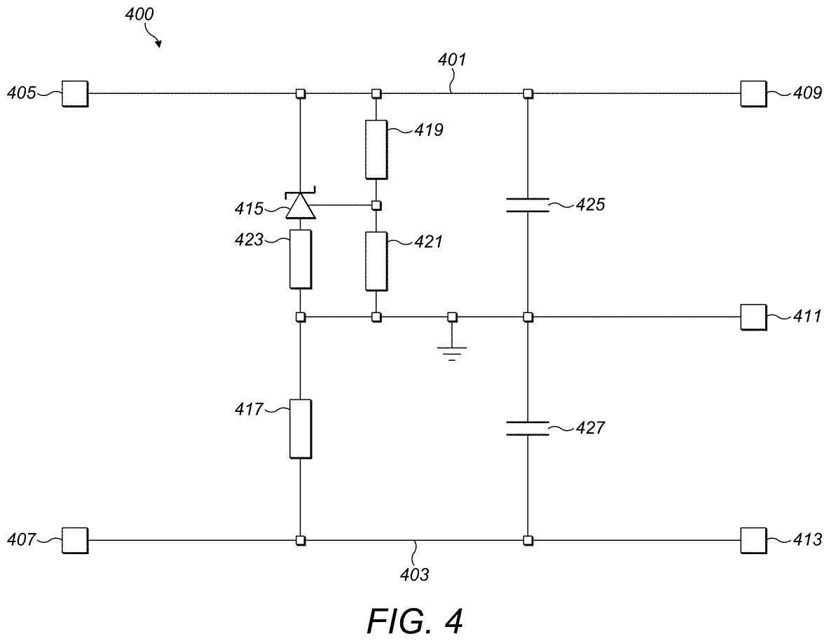

A first example of a known three output DC voltage supply is shown in FIG. 1. This figure shows a three output DC voltage supply 100 without any short circuit protection, and is helpful for understanding the circuits described and shown with respect to FIG. 4.

FIG. 1 shows the three output DC voltage supply circuit 100 including a positive DC voltage bus 101 and a negative DC voltage bus 103. The buses 101 and 103 include input terminals 105 and 107 respectively at their input ends, and output terminals 109 and 113 respectively at their output ends.

The positive voltage input terminal 105 is configured to be connected to the positive side of a DC power supply (not shown). The negative input voltage terminal 107 is configured to be connected to the negative side of the power supply (not shown). It is to be noted that in this description the terminology “positive voltage” and “negative voltage” or the like are relative, such that the positive terminal of the DC voltage supply is positive with respect to the negative terminal of the DC voltage supply, and the negative terminal of the DC voltage supply is negative with respect to the positive terminal of the DC voltage supply.

DC power supplies include power supplies, outputs of DC-DC converters or AC-DC converters, batteries, and any supply which provides a substantially DC voltage supply.

Connected between the positive DC voltage bus 101 and the negative DC voltage bus 103 is a voltage divider which is formed by a Zener diode 115 and a resistor 117. The Zener diode 115 is connected by its cathode to the positive DC voltage bus 101. The output of the voltage divider is formed between the anode of the Zener diode 115 and the resistor 117.

For the purposes of this description, the term resistor is used to mean a component which provides a resistance which can be specified or set by the user. It is noted that other components than a resistor can provide this function, such as a potentiometer, capacitor, coil, inductor, lamp, heating element etc.

The output of the voltage divider provides an intermediate voltage output terminal 111, which provides an intermediate voltage which is negative with respect to the positive output voltage terminal 109 and which is positive with respect to the negative voltage output terminal 113.

For the purposes of this description, the output of a voltage divider is defined as the divided voltage which is supplied from the point where the components of the voltage divider meet.

The Zener diode 115 is sized so as to provide a set voltage drop between the positive voltage output terminal 109 and the intermediate voltage output terminal 111. The resistor 117 is provided to drop the remaining voltage supplied to the positive voltage input terminal 105 and the negative voltage input terminal 107.

Capacitors 125 and 127 are provided for the case where the circuit is used to power a power transistor (not shown), to provide the necessary gate driving currents. If the circuit is not applied to drive a power transistor, then the capacitors 125 and 127 may be omitted.

The circuit 100 of FIG. 1 is suited to applications where the voltage between the positive voltage output terminal 109 and the intermediate voltage output terminal 111 is critical and must be maintained at a precise defined voltage. The Zener diode 115 will provide the correct voltage across these terminals, i.e., the positive voltage output terminal 109 and the intermediate voltage output terminal 111, regardless of the input voltage to the voltage input terminals 105 and 107, provided this input voltage to the voltage input terminals 105 and 107 is larger than this voltage required.

The terms positive, intermediate, and negative are relative. All that is meant by these terms is that: the positive voltage output terminal 109 provides a voltage which is positive with respect to voltages provided by both the intermediate voltage output terminal 111 and the negative voltage output terminal 113. The negative voltage output terminal 113 provides a voltage which is negative with respect to voltages provided by both the intermediate voltage output terminal 111 and the positive voltage output terminal 109. The intermediate voltage output terminal 111 provides a voltage which is negative with respect to the voltage provided by the positive voltage output terminal 109 and which is positive with respect to the voltage provided by the negative voltage output terminal 113.

Where it is desired to provide an intermediate voltage which is 0V, the intermediate voltage output terminal 111 is connected to ground.

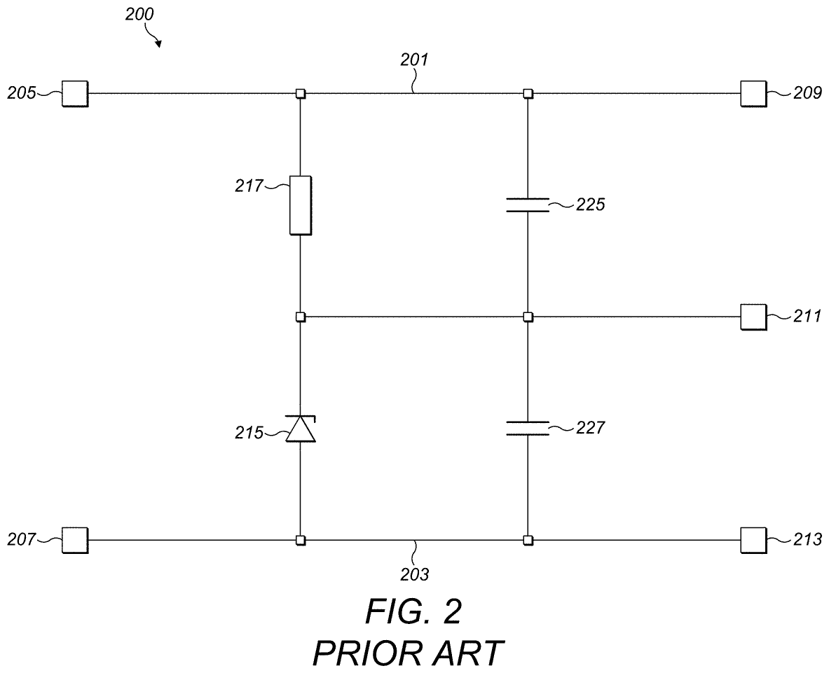

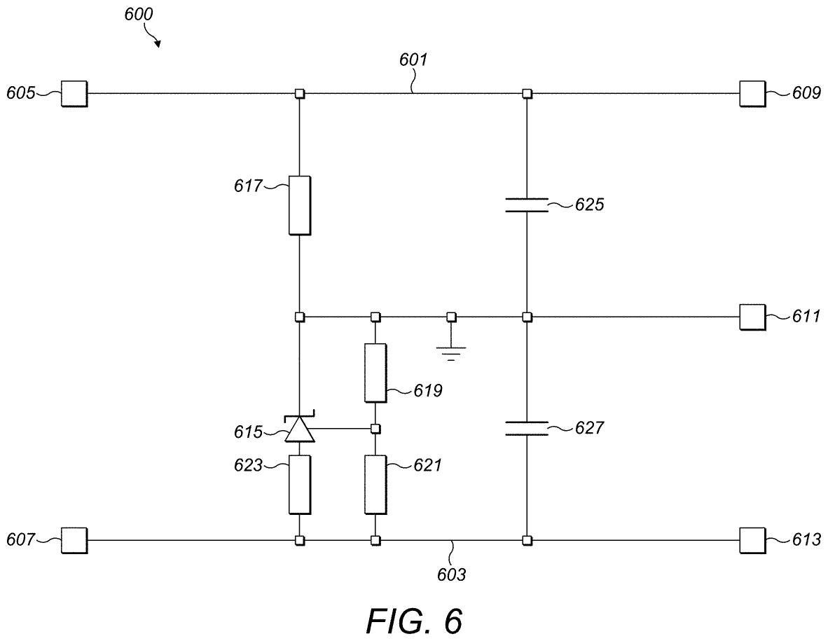

A second example of a known three output DC voltage supply is shown in FIG. 2. This figure shows a three output DC voltage supply 200 without any short circuit protection, and is helpful for understanding the circuits described and shown with respect to FIG. 6.

The circuit 200 works in an identical manner to the circuit 100, except the Zener diode 215 is connected by its anode to the negative DC voltage bus 203, and the output of the first voltage divider is formed by the cathode of the Zener diode 215 and the resistor 217, which is in turn connected to the positive DC voltage bus 201.

Thus, the three output DC voltage supply 200 of FIG. 2 is particularly suited to applications where the voltage between the intermediate voltage output terminal 211 and the negative voltage output terminal 213 is critical and must be maintained at a precise defined voltage. The output of the voltage divider provides an intermediate voltage output terminal 211, which provides an intermediate voltage which is negative with respect to the positive output voltage terminal 209 and which is positive with respect to the negative voltage output terminal 213.

Capacitors 225 and 227 are provided for the case where the circuit is used to power a power transistor (not shown), to provide the necessary gate driving currents. If the circuit is not applied to drive a power transistor, then the capacitors 225 and 227 may be omitted.

A problem with the circuits of FIGS. 1 and 2 is that the Zener diode 115 or 215 provides a fixed voltage drop, which means that if the user desires to use the circuit for a different application, the use would have to change the Zener diode 115 or 215, which is a relatively costly component. A further problem is that a Zener diode matching the exact voltage required may not be available. Furthermore, Zener diodes are not readily available with an accurate voltage tolerance, and the tolerances vary widely over temperature.

A further problem with the circuits of FIGS. 1 and 2 is that if either of the resistors 117 or 217 is bypassed, by a short circuit across the relevant DC voltage terminals, then the full supply voltage is applied across to the Zener diode 115 or 215, which can cause damage to the Zener diode 115 or 215.

For the purpose of the description, the term “short circuit” is used to define a trend as the load connected to the three output DC voltage supply approaches 0Ω.

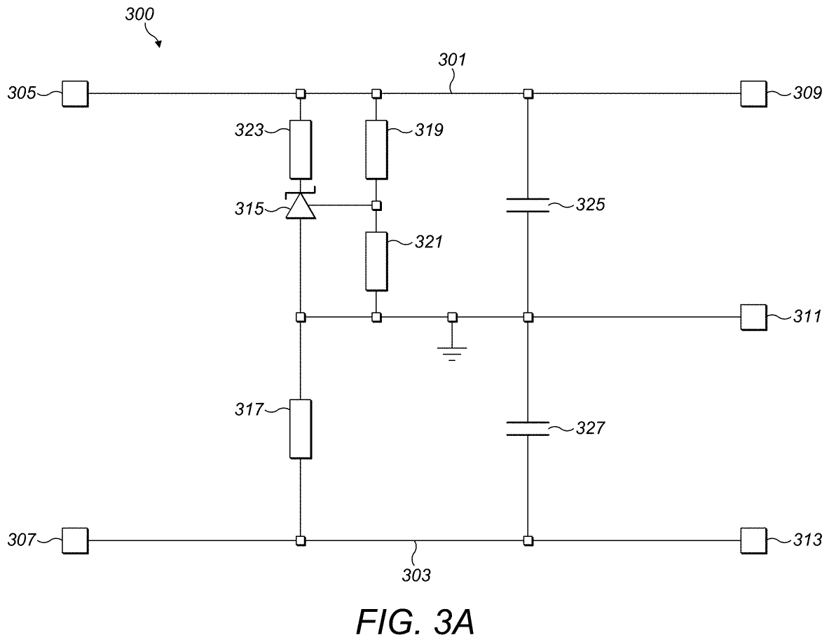

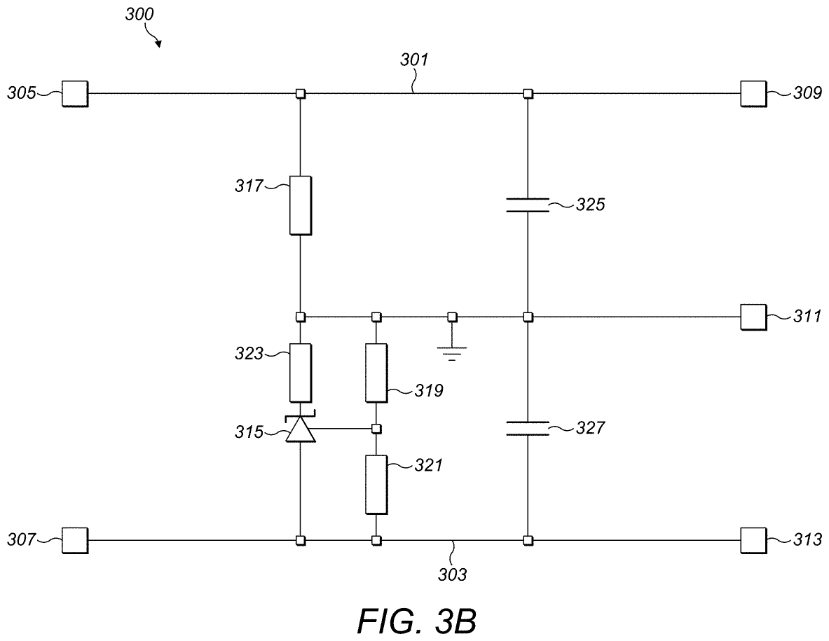

A solution to the problems outlined above is shown by way of a comparative example in FIGS. 3A and 3B. In these circuits 300, a shunt regulator 315 is provided, along with a resistor 323 which limits current to the shunt regulator 323. The shunt regulator 315 sets a voltage between the intermediate voltage output terminal 311 and one of the positive 309 or negative voltage output terminals 313, with this voltage determined by setting resistors 319 and 321. The full operation of the circuit 300 in normal usage is explained with respect to FIG. 4 below. In essence, this is beneficial because the voltage set by the shunt regulator 315 can be adjusted by changing the values of the setting resistors 319 and 321.

The resistor 323 absorbs over voltages applied to the system when a short circuit is presented between the intermediate output voltage terminal 311 and the negative output voltage terminal 313 (in FIG. 3A) and between the positive output voltage terminal 309 and the intermediate output voltage terminal 311 (in FIG. 3B).

However, such a resistor 323 must be relatively large due to the power dissipated through it. Furthermore, the shunt regulator 315 can withstand much higher power than it dissipates due to the limited current caused by the resistor 323, meaning that the resistor 323 would be needlessly large to dissipate this extra power.

An improvement to the circuits 300 of FIGS. 3A and 3B is needed. This is now described with respect to FIGS. 4 to 6.

As shown in FIGS. 4 and 6, the circuits 400 and 600 place a resistor 423, 623 after the shunt regulator 415, 615, that is to a low voltage side of the shunt regulator 415, 615, meaning that the resistor 423, 623 can be smaller as a larger amount of the short circuit power is dissipated by the shunt regulator 415, 615, and furthermore that the shunt regulator 415, 615 is not fully saturated when a fault occurs, due to the current limiting resistor 423, 623 operating in tandem with the voltage setting resistors 419, 421, 619, 621, as is explained in greater detail below.

Capacitors 425, 427, 624, 627 are provided for the case where the circuits are used to power a power transistor (not shown), to provide the necessary gate driving currents. If the circuits are not applied to drive a power transistor, then the capacitors 425, 427, 624, 627 may be omitted.

FIG. 4 shows an adjustable three output DC voltage supply 400 with short circuit protection according to a preferred embodiment of the present invention. This circuit is suitable for applications where the voltage between the positive voltage output terminal 409 and the intermediate voltage output terminal 411 is critical and must be maintained at a precise defined voltage.

The circuit of FIG. 4 includes positive and negative DC voltage buses 401 and 403, each including connected positive and negative voltage input terminals 405 and 407 and positive and negative voltage output terminals 409 and 413. An intermediate voltage output terminal 411 is provided connected to the output of a first voltage divider. The intermediate voltage output terminal 411 is also shown connected to ground, as the particular application requires the intermediate voltage output terminal to be 0V.

The first voltage divider is made of shunt regulator 415, which replaces the Zener diode 115 of the circuit 100 of FIG. 1, and a resistor 417. The output of the first voltage divider becomes the intermediate voltage output terminal 411.

A second voltage divider, including setting resistors 419 and 421 is connected between the output of the first voltage divider and the positive DC voltage bus 401. The output of this voltage divider is connected to a reference input of the shunt regulator 415.

A short circuit protection resistor 423 is located between the shunt regulator 415 and the resistor 417.

The second voltage divider is selected such that the value of the output of the voltage divider provides a set reference voltage, which is required to operate the shunt regulator, once the voltage across the entire voltage divider reaches the required voltage drop which is desired across the positive output voltage terminal 409 and the intermediate voltage terminal 411. The components which include the second voltage divider, resistors 419 and 421 can be considered setting resistors, in that their values set the voltage drop across the positive output voltage terminal 409 and the intermediate voltage terminal 411.

Once the voltage across the second voltage divider reaches this voltage, the output of the voltage divider provides a set reference voltage. This reference voltage is specified by the shunt regulator 415, and is the voltage at which the shunt regulator 415 transitions from providing an open circuit to a short circuit.

Using the example values that the supply voltage is 9 V, the required positive voltage is 6 V, the required negative voltage is −3 V, and the shunt regulator 415 reference voltage is 2.5 V, an example operation is described.

Resistor values for resistor 419=34 KΩ and for resistor 421=26 KΩ provide an output voltage of 2.6 V when 6 V is dropped across the entire second voltage divider. The resistor 423 provides a volt drop of approximately 0.1 V, which is in turn set by the value of the resistor 417 as well as the value of the resistor 423. In this example, the value of the resistor 423 can be as low as 100Ω, or in the range of tens to low hundreds of ohms.

This means that the shunt regulator reference voltage provided by the output of the second voltage divider is 2.5 V when viewed by the shunt regulator 415, because 0.1 V of the 2.6 V is dropped over the resistor 423.

This therefore means that the shunt regulator 415 provides a 6 V voltage drop between the positive output voltage terminal 409 and 411. If the voltage were to rise higher than this over the second voltage divider, the shunt regulator 415 would fully turn on, and the voltage dropped across the second voltage divider would reduce, causing the shunt regulator 415 to turn off.

To remain in a stable position, the shunt regulator 415 operates in a linear region between fully on and fully off to maintain the volt drop at the point where the reference voltage is 2.5 V, which is a value specified by the particular shunt regulator component. In this example, the volt drop is 6 V.

The resistor values will be changed if the specified reference voltage for the shunt regulator 415 is another value other than 2.5 V, but essentially, the resistor values are chosen such that the reference voltage for the shunt regulator 415 is output when the desired output voltage is presented across the resistors.

The resistor values can be changed so that the shunt regulator reference voltage is provided at a different total volt drop across the second voltage divider. Thus, if a different voltage is required at the output terminals this can be achieved by changing the second voltage divider resistor values, in particular the value of resistor 419.

This therefore means that the voltage provided between the positive output voltage terminal 409 and the intermediate output voltage terminal 411 is adjustable by replacing a relatively inexpensive resistor, instead of replacing the comparatively more expensive shunt regulator 415, or Zener diode 115 of FIG. 1. This also means that any voltage can be selected easily.

The resistor 423 is provided to protect the shunt regulator in the event that a short circuit occurs between the intermediate voltage output terminal 411 and the negative voltage output terminal 413.

When the load across the intermediate voltage output terminal 411 and the negative voltage output terminal 413 approaches 0Ω, the effective resistance between the intermediate voltage output terminal 411 and the negative voltage bus 403 tends towards 0Ω. Despite the fact that the resistor 417 is present, the manner in which resistors operate when connected in parallel, as the load is, means that the resistance of the load becomes the dominant resistance and the resistor 417 is effectively bypassed.

This means that the entire supply voltage is applied across the shunt regulator 415 in series with the resistor 423, and across the second voltage divider.

However, because the resistor 423 is present, negative feedback is applied to the reference pin of the shunt regulator 415 as the voltage across the resistor 423 rises. This counteracts the effect of the rising voltage across the second voltage divider. As described above, raising the voltage across the second voltage divider causes the shunt regulator 415 to turn on. In tandem, however, the rising voltage across the resistor 423 causes the shunt regulator 415 to turn off and a balance is reached when 9 V is applied completely across the shunt regulator 415. At this point a safe low current is allowed to pass through the shunt regulator 415, and the power dissipated in the shunt regulator is within the limits of the device, despite being higher than that described with reference to FIGS. 3A and 3B.

The voltage which is not dissipated across the shunt regulator 415 is dissipated across the resistor 423. Furthermore, because the second voltage divider is used to set the reference voltage for the shunt regulator 415, the total current flowing through the resistor 423 and therefore the shunt regulator 415 is limited.

In essence, the DC voltage supply 400 now operates in the manner noted above when there is no short circuit. The output of the second voltage divider increases to, for instance, 3.9 V when the supply voltage is 9 V. This transitions the shunt regulator 415 from off to on, allowing otherwise unrestricted current to flow through the shunt regulator 415 and the resistor 423.

Once, however, 1.4 V (the second voltage divider output voltage minus the reference voltage) appears across the resistor 423, the shunt regulator 415 sees 2.5 V at its reference input, which keeps the circuit stable in the same manner as the operation described above in normal operation.

As the resistor 423 in this example has a value of 100 Ω, the total current through the resistor 423 and the shunt regulator 415 is 14 mA, which because of the action of the second voltage divider, becomes the maximum current through the resistor 423 and the shunt regulator 415.

It is noted that the resistor 423 could be provided to the circuit 100 of FIG. 1; however, this would have a reduced effect because there is no stability circuit provided by the second voltage divider. The entire supply voltage would be permitted through the Zener diode 115, and the provided resistor would need to dissipate this voltage leading to a total fault current of almost 100 mA. The value of the provided resistor would therefore need to be higher to reduce the fault current, and thus power losses in normal use would be higher than in the circuit of FIG. 1.

Reference to a shunt regulator in the specification refers to any component or arrangement of components which can transition between an on and off when a reference voltage is applied. For instance, a circuit involving a comparator which compares an input voltage to a reference voltage and activates a transistor, in some preferred embodiments to bypass a diode is appropriate. Furthermore, the comparator can be omitted if the gate or base voltage of the transistor requires a suitable reference voltage. As another example, a field effect transistor including a body diode and an applicable gate voltage is appropriate. As a further example, a Zener diode with a reference voltage is appropriate.

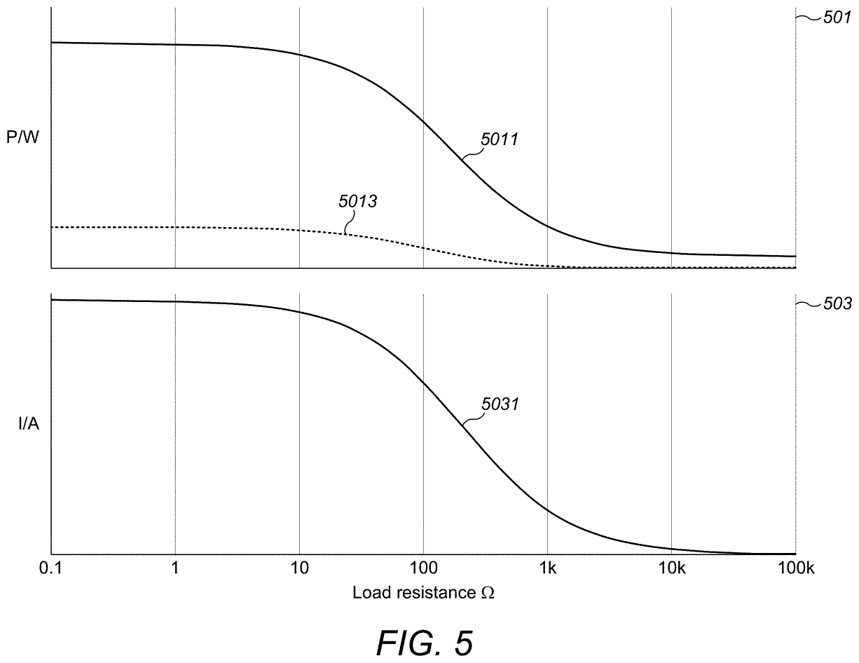

The action of the DC voltage supply 400 of FIG. 4 is illustrated by the graphs of FIG. 5.

Graph 501 shows power dissipation through the shunt regulator 415 by the line 5011 and also shows the power dissipation through the resistor 423 by the line 5013.

It can be seen that as the load resistance approaches 0 Ω, the power dissipated through the shunt regulator 415 rises, until the action of the second voltage divider with the resistor 423 prevents any further power being dissipated.

The same is shown for the resistor 423, whereby as the load approaches 0Ω, the power dissipated through the resistor 423 rises up to a point and then levels off due to the action of the second voltage divider. With the values noted above, where the resistor 423 has a value of 100Ω, and the current through it is 14 mA, the power dissipated can be shown to be just less than 20 mW.

The power through the shunt regulator 415 tracks this line, and with 7.6 V essentially applied across the shunt regulator 415, the power dissipated is around 100 mW.

The points on both lines 5011 and 5013 where the power stops rising and begins to level off is the point where the shunt regulator 415 is in its transition period, and as such the “level off” of the lines happens when the shunt regulator 415 sees 2.5 V at its reference input as discussed above.

The line 5031 of graph 503 shows this, as it shows the current at the “cathode” of the shunt regulator 415, and the level off is at 14 mA as discussed above.

The values used to illustrate these two graphs 501 and 503 are merely exemplary, and relate to the specific resistor values and voltage values used in describing the circuit above. Any set of input voltages, output voltages, reference voltages, resistances and the like can be picked depending on the application. The description above illustrates the principles by which these values can be chosen.

FIG. 6 shows a DC voltage supply 600 according to a preferred embodiment of the present invention, whereby the critical voltage is the voltage between the negative voltage output terminal 613 and the intermediate voltage output terminal 611 and must be maintained at a precise defined voltage.

The operation of the DC voltage supply 600 is the same as in the above described example DC voltage supply 400 of FIG. 4, except that the shunt regulator 615 provides a set voltage between the intermediate voltage output terminal 611 and the negative voltage output terminal 613. The circuit of FIG. 6 includes positive and negative DC voltage buses 601 and 603, each including connected positive and negative voltage input terminals 605 and 607 and positive and negative voltage output terminals 609 and 613. When the voltage applied across the second voltage divider of resistors 619 and 621 reaches the required voltage output between the intermediate and negative output voltage terminals 611 and 613, the resistors 619 and 621 are so sized as to provide the required reference voltage for the shunt regulator 615. The current limiting resistor 623 provides a further voltage drop such that the setting resistors 619 and 621 are sized to output the reference voltage plus the voltage drop.

When the load applied across the positive voltage output terminal 609 and the intermediate voltage output terminal 611 approaches 0Ω, as in a short circuit, the entire supply voltage is applied across the resistor 623 and the shunt regulator 615, and the resistor 617 is bypassed. This provides an output of the second voltage divider which is much higher than the required reference input voltage to the shunt regulator 615, and so the shunt regulator 615 transitions to provide a short circuit, allowing voltage to be applied to the resistor 623. Once a voltage equal to the second voltage divider output minus the required reference input voltage to the shunt regulator 615 is dissipated over the resistor 623, the shunt regulator 615 begins to transition back to an open circuit, and puts the circuit 600 into a stable position.

If all of the values selected for the DC voltage supply 600 are the same as the circuit 400, then the circuit 600 will present the same voltage difference between the intermediate voltage output terminal 611 and the negative voltage output terminal 613 as the circuit 400 presents between the positive voltage output terminal 409 and the intermediate voltage output terminal 611. The value of the setting resistors 619 and 621 can be altered to provide the necessary shunt regulator reference voltage at a different voltage drop across the intermediate voltage output terminal 611 and the negative voltage output terminal 613. This therefore means that this voltage is adjustable by replacing a relatively inexpensive resistor, instead of replacing the comparatively more expensive shunt regulator 615, or the Zener diode 215 of FIG. 2.

With both the DC voltage supply 400 of FIG. 4 and the DC voltage supply 600 of FIG. 6, and as noted above, a short circuit is where the load across the respective terminals approaches 0Ω. As this happens, more of the supply voltage than originally required is dissipated over the shunt regulator 415 or 615, because the load resistance is not capable of dissipating the remaining voltage. As this load approaches 0Ω, it may not be the entire supply voltage which is presented to the shunt regulator 415 or 615 or the second voltage divider, and so the resistor 423 or 623 may not dissipate its full expected voltage, but a proportion thereof. That is to say, that the voltages dissipated across all of the components is proportional to the extent of the short circuit.

Throughout the figures the intermediate voltage output terminal is shown connected to ground. The intermediate voltage output terminal is connected to ground when it is required that the intermediate voltage output is 0 V, which, as described above, is not always the case. When it is not required that the intermediate voltage output is 0 V, the terminal will not be connected to ground, and the ground connection shown on the figures will therefore be omitted.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An adjustable three output DC voltage supply for providing a positive, intermediate, and negative voltage supply, comprising:
a positive DC voltage bus and a negative DC voltage bus that connect to a DC power source;
a first voltage divider connected between the positive DC voltage bus and the negative DC voltage bus, wherein the first voltage divider includes a shunt regulator that includes a reference input, and wherein an output of the first voltage divider provides the intermediate voltage supply;
a second voltage divider connected between the intermediate voltage supply and one of the positive DC voltage bus or the negative DC voltage bus, wherein an output of the second voltage divider is connected to the reference input of the shunt regulator; and
a short circuit protection component connected in series to a low voltage side of the shunt regulator to limit the current through the shunt regulator in case of a short circuit to the intermediate voltage supply.

2. The adjustable three output DC voltage supply according to claim 1, wherein the first voltage divider includes a resistor.

3. The adjustable three output DC voltage supply according to claim 2, wherein the shunt regulator is connected to the positive DC voltage bus via the resistor.

4. The adjustable three output DC voltage supply according to claim 1, wherein the shunt regulator is connected to the negative DC voltage bus via a resistor.

5. The adjustable three output DC voltage supply according to claim 1, wherein the short circuit protection component is connected between the shunt regulator and the output of the first voltage divider.

6. The adjustable three output DC voltage supply according to claim 1, wherein the short circuit protection component is connected to the negative DC voltage bus.

7. The adjustable three output DC voltage supply according to claim 6, wherein the shunt regulator is connected between the short circuit protection component and the output of the first voltage divider.

8. The adjustable three output DC voltage supply according to claim 1, wherein the shunt regulator includes a transistor.

9. The adjustable three output DC voltage supply according to claim 8, wherein the shunt regulator further includes a comparator that operates the transistor when an input voltage to the comparator is higher than the reference input of the shunt regulator.

10. The adjustable three output DC voltage supply according to claim 8, wherein the transistor includes a Bipolar Junction Transistor.

11. The adjustable three output DC voltage supply according to claim 8, wherein the transistor includes an intrinsic diode or a body diode.

12. The adjustable three output DC voltage supply according to claim 11, wherein the transistor includes a Field Effect Transistor.

13. The adjustable three output DC voltage supply according to claim 1, wherein the shunt regulator includes an adjustable reference diode.

14. The adjustable three output DC voltage supply according to claim 1, wherein the short circuit protection component includes a short circuit protection resistor.

15. The adjustable three output DC voltage supply according to claim 1, wherein the second voltage divider includes a first setting resistor and a second setting resistor.

16. The adjustable three output DC voltage supply according to claim 1, wherein the DC power source is provided by a rectified output from a transformer.

17. The adjustable three output DC voltage power supply according to claim 1, wherein the intermediate voltage supply defines a 0V voltage supply.
